(19) United States
(12) Patent Application Publication
(10) Pub. No.: US 2008/0106153 A1
(43) Pub. Date: May 8, 2008

(54) Power Supply Method for Circuit Block of Radio-Use Semiconductor Apparatus and Radio-Use Semiconductor Apparatus

(75) Inventors: Takashi Aoyama, Aichi (JP); Hiroshi Miyagi, Yokohama (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: NIIGATA SEIMITSU CO., LTD., NIIGATA JAPAN (JP)

(21) Appl. No.: 11/791,576

(22) PCT Filed: Sep. 29, 2005
(86) PCT No.: PCT/JP05/17971

§ 371 Date: Sep. 6, 2007

(30) Foreign Application Priority Data
Nov. 29, 2004 (JP) 2004-344744

(51) Int. Cl. H01B 7/30; H01L 27/04

(52) U.S. Cl. 307/147

(57) ABSTRACT

The purpose of the present invention is to reduce the noise of an analog circuit of a radio-use semiconductor apparatus. A power supply voltage is supplied to a low-noise amplifier 12 and a partial circuit of a stereo demodulation circuit 16 from an analog-use power supply. A power supply voltage is supplied to a digital circuit 19, an MPXPLL 17, and pilot signal detection circuit 18 of the stereo demodulation circuit 16 from a digital-use power supply that is separate from the analog-use power supply. This configuration prevents noise generated in a digital circuit from propagating to the analog circuit within the stereo demodulation circuit.

### TECHNICAL FIELD

The present invention relates to a radio-use semiconductor apparatus and a method for supplying a circuit block thereof with power.

### BACKGROUND ART

In the designing of a semiconductor integrated circuit (IC), a block is configured for each function of a circuit and each block is connected to one or a plurality of power supply pads and ground pads by bundling the power supply wires and ground wires of the respective circuit blocks. With this configuration, digital circuits and analog circuits preferably receive mutually different power supplies in order to prevent invasive noise.

Reference patent document 1 notes a method for connecting a power supply wire or ground wire of a different system by way of a resistor or high-resistance wire formed on a circuit board in an electronic circuit having a plurality of power supply systems so as to prevent the occurrence of a latch-up or other such problem due to a shift in the rise time of an individual power supply system.

Reference patent document 2 notes a method for separating a ground terminal of a local oscillation signal buffer amplifier that amplifies a local oscillation signal from a ground terminal of a mixer circuit, thereby preventing a voltage variation at the ground terminal resulting from a current flow in the mixer circuit from influencing the local oscillation signal buffer amplification circuit.

Separating the power supply wires and ground wires of a digital circuit from those of an analog circuit is a common practice. When configuring a circuit block for each function of a radio-use IC, there is a possibility that analog circuits and digital circuits will be intermingled in one functional circuit block; in this case, whether or not the analog circuit will be influenced by the noise of another circuit within the same circuit block has not conventionally been well considered.

Another conventional practice is to form a guard ring around a circuit block of a digital circuit and ground it by connecting the guard ring to a circuit board. However, the use of the guard ring has not necessarily been able to reduce the noise of an analog circuit.

Patent document 1: Laid-Open Japanese Patent Application Publication No. H05-292663

Patent document 2: Laid-Open Japanese Patent Application Publication No. 2000-91848

### DISCLOSURE OF INVENTION

The objective of the present invention is to reduce the noise of an analog circuit of a radio-use semiconductor apparatus.

The present invention is a method for supplying, to a circuit block of a radio-use semiconductor apparatus comprising at least a low-noise amplifier, a digital circuit and a stereo demodulation circuit with a power supply, comprising: separating power supply wires and ground wires of a pilot signal detection circuit and power supply wires and ground wires of a secondary carrier wave generation circuit generating a secondary carrier wave signal, both of which are of the stereo demodulation circuit, from power supply wires and ground wires of an analog circuit of the low noise amplifier and stereo demodulation circuit.

The present invention is contrived to separate the power supply wires and ground wires of the pilot signal detection circuit (which is a digital circuit) and the power supply wires and ground wires of a secondary carrier wave generation circuit, both of which are part of the stereo demodulation circuit, from the wires of the analog circuit of the low-noise amplifier and stereo demodulation circuit, thereby making it possible to prevent noise generated in the digital circuit and such of the stereo demodulation circuit from invading a signal line of the analog circuit.

Another aspect of the power supplying method is configured to form a guard ring so as to enclose respectively the digital circuit, and a pilot signal detection circuit and a secondary carrier wave generation circuit of a pilot signal, both of which are part of a stereo demodulation circuit; this configuration comprises no contact between the guard ring and a semiconductor board.

Another aspect of the power supplying method is configured to form a guard ring so as to enclose respectively the digital circuit, and a pilot signal detection circuit and a secondary carrier wave generation circuit of a pilot signal, both of which are part of a stereo demodulation circuit, wherein the guard ring and a semiconductor board have a resistance equal to or greater than a predetermined value.

This configuration makes it possible to prevent noise generated in the digital circuit, the pilot signal detection circuit of the stereo demodulation circuit, and the secondary carrier wave generation circuit from invading the low-noise amplifier or a signal line of the analog circuit of the stereo demodulation circuit by way of a circuit board.

Another aspect of the power supplying method is configured such that the pilot signal detection circuit comprises an offset cancellation circuit that operates on the basis of a clock signal supplied from the digital circuit.

Thus separating the power supply wires and ground wires of the pilot signal detection circuit from the power supply wires and ground wires of the analog circuit makes it possible to prevent noise generated in the offset cancellation circuit included in the pilot signal detection circuit of the stereo demodulation circuit from influencing the low-noise amplifier and other components.

The power supplying method is configured to connect a pilot signal detection circuit of the stereo demodulation circuit, a secondary carrier wave generation circuit, power supply wires and ground wires of a digital circuit, and power supply wires and ground wires of an analog circuit to respectively separate pads.

This configuration makes it possible to prevent noise generated in the digital circuit or digital circuit of the stereo demodulation circuit from invading the low-noise amplifier and the analog circuit of the stereo demodulation circuit.

### BRIEF DESCRIPTION OF DRAWINGS

FIG. 1 is a diagram describing a power supplying method for a circuit block of a semiconductor integrated circuit according to a preferred embodiment; and

FIG. 2 is a diagram showing a circuit model used for a simulation.

### BEST MODE FOR CARRYING OUT THE INVENTION

The following is a detailed description of the preferred embodiment of the present invention, referring to the accompanying drawings.

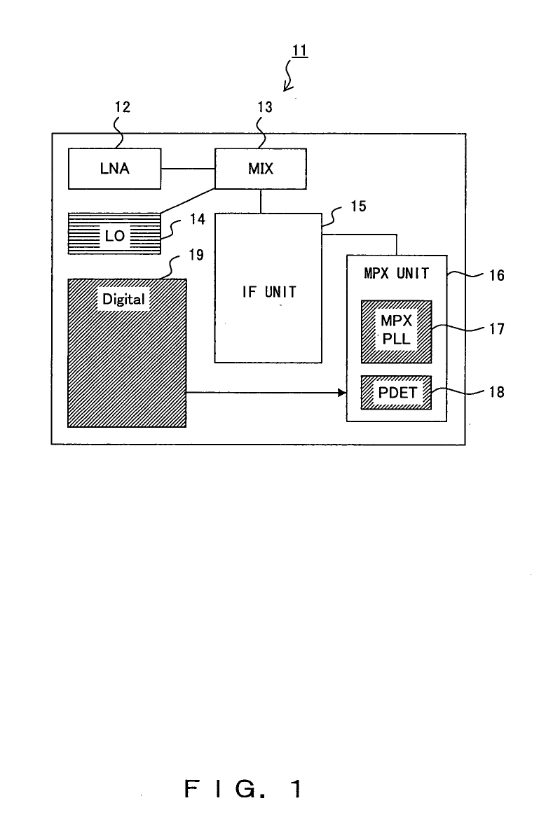

FIG. 1 is a diagram describing a power supplying method for a circuit block of a radio-use semiconductor integrated circuit (i.e., a semiconductor apparatus) 11 according to a preferred embodiment.

The radio-use semiconductor integrated circuit 11 comprises a p-channel MOS transistor and an n-channel MOS transistor, both of which are formed on a P-type circuit board.

Referring to FIG. 1, a low-noise amplifier (LNA) 12 amplifies a radio signal received at an antenna (not shown herein) and outputs it to a mixer circuit (MIX) 13 which in turn mixes the received signal with a local oscillation signal generated by a local oscillation (LO) circuit 14 and converts it into an intermediate frequency signal. An IF unit 15 amplifies the intermediate frequency signal and detects it, and a stereo demodulation circuit (MPX unit) 16 demodulates it to a stereo signal.

The stereo demodulation circuit 16 comprises digital circuits such as an MPXPLL (secondary carrier wave generation circuit) 17 that extracts a stereo secondary carrier wave signal from a stereo multiplex signal, and a pilot signal detection circuit (PDET) 18 that detects a pilot signal in the stereo multiplex signal.

The MPXPLL 17 comprises a voltage control oscillator in which a noise is also generated. The pilot signal detection circuit 18 comprises an offset cancellation circuit operating on the basis of a clock signal output from a digital circuit 19. The offset cancellation circuit is also a noise generation source.

The digital circuit 19 comprises circuits such as a logic circuit and a frequency synthesizer for generating a signal of a frequency constituting a reference.

The inventors of the present invention (“present inventers” hereinafter) have analyzed noise of the low-noise amplifier 12 of the radio-use semiconductor integrated circuit 11, and have discovered that the frequency of the noise has a relationship with a signal generated in the digital circuit 19 or with an oscillation frequency of a voltage control oscillator or other such device within the stereo demodulation circuit 16. Also discovered is that noise generated in the MPXPLL 17 generating a stereo secondary carrier wave of the stereo demodulation circuit 16 and noise generated in the pilot signal detection circuit 18 also exert an influence.

On the basis of the above findings, a new configuration has been created: the power supply wires and ground wires for the analog circuit of the stereo demodulation circuit 16 are connected to a power supply pad and ground pad of an analog-use power supply, thereby supplying the power from an analog-use power supply (not shown herein), and the power supply wires and ground wires for the MPXPLL 17 of the digital circuit and pilot signal detection circuit 18 are connected to a power supply pad and ground pad of a digital-use power supply, thereby supplying the power supply voltage from a digital-use power supply (not shown herein) as opposed to the conventional circuit in which the voltage is supplied to the entirety of the stereo demodulation circuit 16 from an analog-use power supply.

Specifically, the power supply voltage is supplied to a circuit block of the analog circuits indicated by white in FIG. 1, that is, the low-noise amplifier 12, mixer circuit 13, IF unit 15 and stereo demodulation circuit 16, from the analog-use power supply.

The power supply voltage is supplied to the digital circuit 19 and the MPXPLL 17 and pilot signal detection circuit 18 of the stereo demodulation circuit 16, which are shown by diagonal hatching, from a digital-use power supply that is separate from the analog-use power supply.

Furthermore, the power supply voltage is supplied to the local oscillator 14 of the circuit block indicated by horizontal hatching in FIG. 1 from another power supply.

That is, even if a circuit belongs to the same stereo demodulation circuit 16, the MPXPLL 17 and pilot signal detection circuit 18, which are deemed to be noise generation sources, are connected to a digital-use power supply, and analog circuits are connected to an analog-use circuit, thereby separating the power supply wires and ground wires of these circuits from those of the other circuits.

This configuration prevents noise resulting from signals output from the digital circuit 19 or noise generated in a circuit comprising a voltage control oscillator from propagating to an analog circuit such as the low-noise amplifier 12, resulting in the suppression of the noise of a reception signal. Lowering the noise level on the input side of the low-noise amplifier 12 makes it possible to lower the receivable signal level, thereby enabling an improvement in reception sensitivity.

Note that the preferred embodiment is configured to minimize the size of a buffer of the digital circuit to reduce the lead-through current of the buffer, thereby further reducing noise. Also configured is the lowering of the frequency of a clock signal within the digital circuit 19 as much as possible, thereby suppressing noise invading a frequency band of a radio broadcast.

Next, the present inventors have conducted a simulation by employing a circuit model as follows in order to examine the influence of the propagation of noise by a P-type circuit board used for the radio-use semiconductor integrated circuit 11.

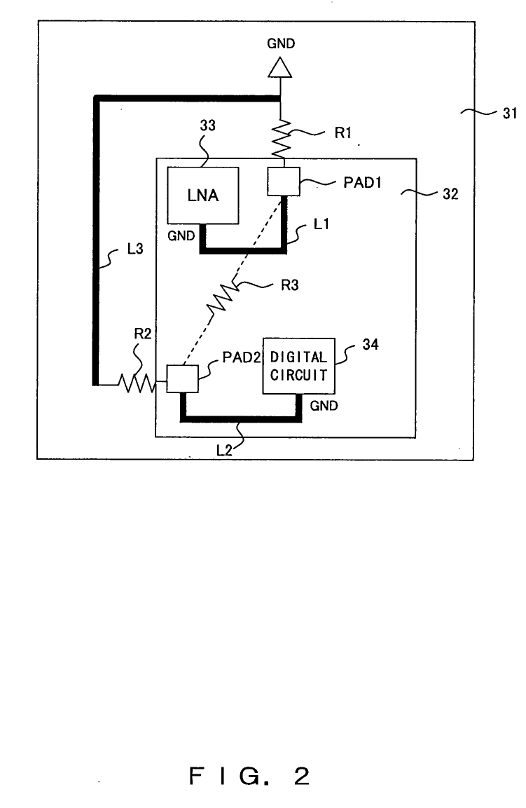

FIG. 2 is a diagram showing a simulation-use circuit model used for examining the influence of the P-type circuit board of a radio-use IC 32 on noise.

The low-noise amplifier 33 is connected to ground pad PAD1 by ground wire L1, and ground pad PAD1 is connected to the ground of a printed circuit board 31 by wire resistor R1, which indicates the resistance value of the wire connected between ground pad PAD1 and an external connection terminal of the IC 32. Ground pad PAD1 corresponds to the ground of the power supply of the analog circuit shown in FIG. 1.

The digital circuit 34 is connected to ground pad PAD2 by ground wire L2, and ground pad PAD2 is connected to the ground of the printed circuit board 31 by way of wire resistor R2 and ground wire L3. Wire resistor R2 indicates the resistance value of the wire connected between ground pad PAD2 and an external connection terminal of the IC 32. Ground pad PAD2 corresponds to the ground of the digital circuit 19 shown in FIG. 1. In addition, resistor R3 indicates an equivalent resistance value for the P-type circuit board (which constitutes the ground of the IC 32) between ground pads PAD1 and PAD2.

In the above described circuit, changing the value of the equivalent resistance R3 of the P-type circuit board and measuring the input noise of the low-noise amplifier 33 by operating the digital circuit 32 show that the noise at the input side of the low-noise amplifier 33 decreases with an increase inresistance R3.

In addition, the input noise of the low-noise amplifier 33 decreases with a decrease in the resistance value of the wire resistors R1 and R2.

This result indicates that noise generated in the digital circuit 34 is propagated to the input side of the low-noise amplifier 33 by way of the P-type circuit board.

That is, the above result shows that the propagation of noise is reduced by not connecting the guard ring surrounding the digital circuit of a noise generation source to the circuit board.

Accordingly, the present embodiment is configured to not feature a contact between the P-type circuit board and the guard ring formed around the digital circuit 19, the MPXPLL 17 and pilot signal detection circuit 18 of the stereo demodulation circuit 16, which are generation sources of noise.

This configuration makes it possible to prevent the noise generated in the digital circuit 19, MPXPLL 17, and such from propagating to the low-noise amplifier 12 or to another analog circuit by going through the P-type circuit board. Therefore, the noise level of an analog circuit such as the low noise amplifier 12 can be reduced and reception sensitivity can be improved.

The present invention provides an increased benefit for use in a radio-use semiconductor apparatus having two or three series of external power supply terminals. That is, noise is reduced and sensitivity is improved, and also a low-cost one-chip IC can be implemented for use in a semiconductor apparatus having two or three series of external power terminals.

The present invention makes it possible to prevent noise generated in a digital circuit or a pilot signal detection circuit and secondary carrier wave generation circuit of a stereo demodulation circuit from invading a low noise amplifier and an analog circuit of the stereo demodulation circuit. Furthermore, a configuration in which a guard ring formed around the digital circuit and the like is not connected to the circuit board enables the suppression of noise propagation.

Not limited to the embodiment described above, the present invention may be, for example, configured as follows:

(1) The preferred embodiment describes the case of supplying the power for the MPXPLL 17 and pilot signal detection circuit 18 of the stereo demodulation circuit 16 from another power supply that is separate from an analog-use power supply. This can be applied to a digital circuit included in another circuit block in lieu of being limited to the stereo demodulation circuit 16.

(2) The connection resistance value between the guard ring and circuit board may be increased (e.g., 40 ohms or higher) in lieu of eliminating contact between the guard ring of a circuit block of a noise generation source and the circuit board.

(3) The connection between the guard ring of an analog circuit and circuit board may be eliminated to preventing the propagation of noise in lieu of eliminating the connection between the guard ring of the digital circuit and circuit board.

1. A power supplying method for supplying a circuit block of a radio-use semiconductor apparatus comprising at least a low noise amplifier, a digital circuit and a stereo demodulation circuit with a power supply, comprising
separating power supply wires and ground wires of a pilot signal detection circuit and power supply wires and ground wires of a secondary carrier wave generation circuit generating a secondary carrier wave signal, both of which are of the stereo demodulation circuit, from power supply wires and ground wires of an analog circuit of the low noise amplifier and stereo demodulation circuit.

2. The power supplying method for the circuit block of the radio-use semiconductor apparatus according to claim 1,
forming a guard ring so as to enclose respectively said digital circuit along with a pilot signal detection circuit and a secondary carrier wave generation circuit of a pilot signal, both of which are of the stereo demodulation circuit, and comprising no contact between the guard ring and a semiconductor board.

3. The power supplying method for the circuit block of the radio-use semiconductor apparatus according to claim 1,
forming a guard ring so as to enclose respectively said digital circuit along with a pilot signal detection circuit and a secondary carrier wave generation circuit of a pilot signal, both of which are of the stereo demodulation circuit, wherein
the guard ring and a semiconductor board have a resistance equal to or greater than a predetermined value.

4. The power supplying method for the circuit block of the radio-use semiconductor apparatus according to claim 1, wherein
said pilot signal detection circuit comprises an offset cancellation circuit that operates on the basis of a clock signal supplied from said digital circuit.

5. The power supplying method for the circuit block of the radio-use semiconductor apparatus according to claim 1,
connecting a pilot signal detection circuit of said stereo demodulation circuit, a secondary carrier wave generation circuit, power supply wires and ground wires of a digital circuit, and power supply wires and ground wires of an analog circuit to respectively separate pads.

6. A radio-use semiconductor apparatus comprising a low-noise amplifier, a digital circuit and a stereo demodulation circuit,
separating power supply wires and ground wires of a pilot signal detection circuit of the stereo demodulation circuit and power supply wires and ground wires of a secondary carrier wave generation circuit for generating a secondary carrier wave signal from power supply wires and ground wires of analog circuits of the low-noise amplifier and stereo demodulation circuit, and supplying the separated power supply wires with voltage from respectively different power sources.

7. The radio-use semiconductor apparatus according to claim 6,
forming a guard ring so as to enclose respectively said digital circuit along with a pilot signal detection circuit and a secondary carrier wave generation circuit of a pilot signal, both of which are of a stereo demodulation circuit, and comprising no contact between the guard ring and a semiconductor board.
